(19) United States
(12) Patent Application Publication
(10) Pub. No.: US 2014/0317462 A1
(43) Pub. Date: Oct. 23, 2014

(54) SCANNABLE SEQUENTIAL ELEMENTS

(71) Applicant: Broadcom Corporation, Irvine, CA (US)

(72) Inventors: David Money HARRIS, Upland, CA (US); Paul Ivan PENZES, Irvine, CA (US)

(73) Assignee: Broadcom Corporation, Irvine, CA (US)

(21) Appl. No.: 13/899,486

(22) Filed: May 21, 2013

Related U.S. Application Data
(60) Provisional application No. 61/813,536, filed on Apr. 18, 2013.

(51) Int. Cl. G01R 31/3185

(52) U.S. Cl. CPC G01R 31/318536
USPC 714/726

(57) ABSTRACT

A scannable sequential element is provided. The scannable sequential element includes a master stage that includes a data path configured to receive a data input. The master stage also includes a pass gate located on the data path and configured to selectively pass the data input, in which the data path has only one pass gate. The master stage also includes a test path coupled to the data path and configured to receive a test input. The master stage also includes pass gates located on the test path and configured to selectively pass the test input.

### CROSS-REFERENCE TO RELATED APPLICATIONS

The present application claims the benefit of U.S. Provisional Patent Application Ser. No. 61/813,536, titled “SCANNABLE SEQUENTIAL ELEMENTS,” filed on Apr. 18, 2013, which is hereby incorporated by reference in its entirety for all purposes.

### BACKGROUND

Sequential elements such as flip-flops or latches are conventional building blocks in sequential digital circuits. A sequential element typically has a data input, a clock input, and a data output. The data input is copied to the data output at a time controlled by the clock. Sequential elements have timing attributes including setup time, hold time, and clock-to-Q delay describing the timing relationships between the data input, clock input, and data output. Scannable sequential elements may also provide a test input and a test enable signal so that the elements can be configured into a scan chain, facilitating testing the digital circuits. Such elements have additional timing attributes related to the test input instead of the data input.

### SUMMARY

A system and/or circuit is provided for scannable sequential elements, substantially as illustrated by and/or described in connection with at least one of the figures, as set forth more completely in the claims.

### BRIEF DESCRIPTION OF THE DRAWINGS

Certain features of the subject disclosure are set forth in the appended claims. However, for purpose of explanation, several implementations of the subject disclosure are set forth in the following figures.

FIG. 1A is a diagram illustrating a scannable sequential element according to one or more implementations.

FIG. 1B is a diagram illustrating a digital circuit with scannable sequential elements connected in a scan chain according to one or more implementations.

FIG. 2 is a diagram illustrating a timing diagram of a sequential element according to one or more implementations.

FIG. 3 is a diagram illustrating a transistor-level design of a scannable sequential element according to one or more implementations.

FIG. 4 is a diagram illustrating a scannable sequential element according to one or more implementations.

FIG. 5 is a diagram illustrating another scannable sequential element according to one or more implementations.

FIG. 6 is a diagram illustrating a transparency window according to one or more implementations.

FIG. 7 is a diagram illustrating a gated clock generator producing a wider transparency window according to one or more implementations.

FIGS. 8A-8C are diagrams illustrating various weak feedback tristates inverters according to one or more implementations.

FIG. 9 is a diagram illustrating a sequencing overhead of a scannable sequential element according to one or more implementations.

### DETAILED DESCRIPTION

It is understood that other configurations of the subject disclosure will become readily apparent to those skilled in the art from the following detailed description, wherein various configurations of the subject disclosure are shown and described by way of illustration. As will be realized, the subject disclosure is capable of other and different configurations and its several details are capable of modification in various other respects, all without departing from the scope of the subject disclosure. Accordingly, the drawings and detailed description are to be regarded as illustrative in nature and not as restrictive.

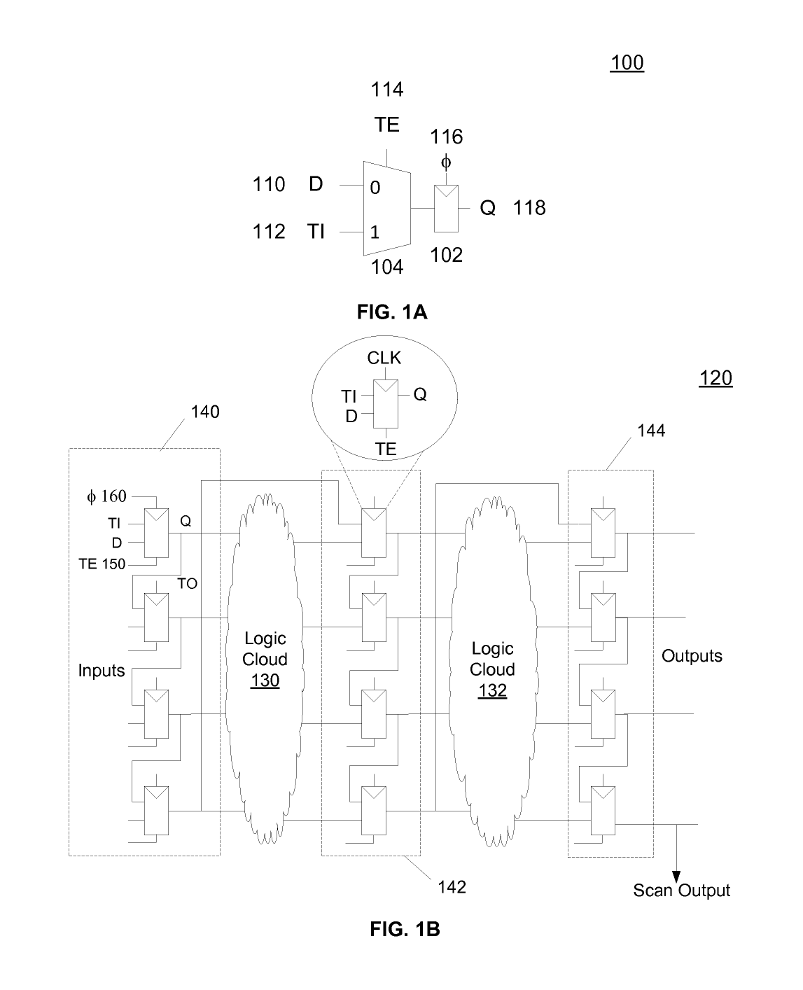

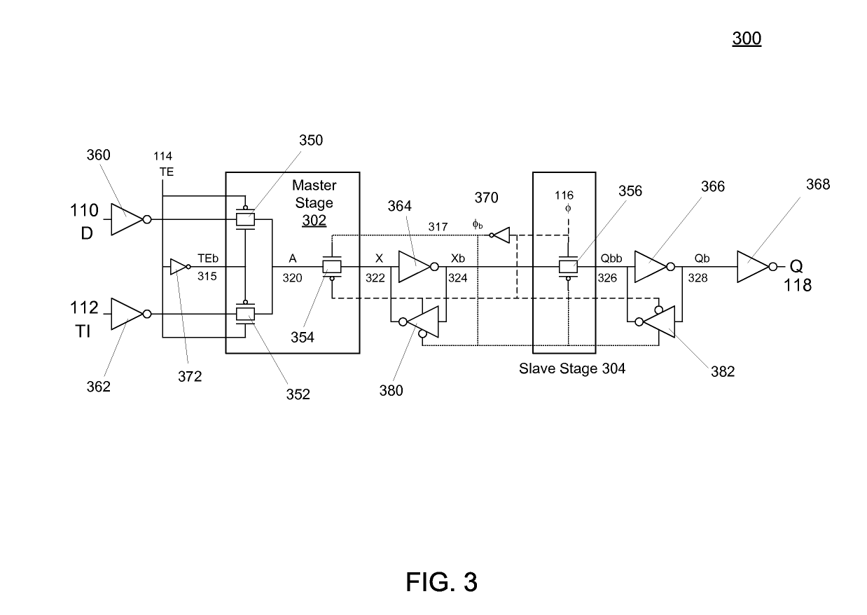

FIG. 1A is a diagram illustrating a scannable flip-flop 100 (a flip-flop, for short) according to one or more implementations. The scannable flip-flop 100 is, for example, a scannable positive-edge-triggered flip-flop. The scannable flip-flop 100 includes a flip-flop 102 and a multiplexer 104. The scannable flip-flop 100 is logically formed from the ordinary flip-flop 102 that holds the state and the multiplexer 104 that selects between the data and test inputs. However, in accordance with one or more implementations, the multiplexer 104 is integrated into a master stage of the flip-flop 102, as will be illustrated with reference to FIG. 3. The scannable flip-flop 100 has a data input D 110, a test input TI 112, a test enable input TE 114, a clock φ 116, and a data output Q 118. The clock 116 oscillates between a logic low value and a logic high value. The scannable flip-flop samples its input on the rising edge of the clock 116. When test enable input 114 is a logical low (or “0”), the scannable flip-flop 100 is in normal mode and it copies data from the data input 110 to the data output 118 on the rising edge of the clock 116. When test enable input 114 is a logical high value (or “1”), the scannable flip-flop 100 is in test mode and it copies data from the test input 112 to the data output 118 on the rising edge of the clock 116. In accordance with another implementation, the polarity of the test enable input 114 is reversed.

In one or more aspects, a sequential element (e.g., flip-flop 102) is a digital element whose output depends on previous as well as current inputs. In other words, the element has memory or retains state. A sequential element can be used to keep data in sequence as it moves through a digital pipeline or finite state machine. Examples of sequential elements include positive-edge-triggered flip-flops, negative-edge-triggered flip-flops, dual-edge-triggered flip-flops, pulsed latches, two-phase latches, Muller C elements, and others. Scannable sequential elements can choose between an ordinary input and a test input based on a test enable signal. The figures in this disclosure illustrate scannable positive-edge triggered flip-flops, but the subject disclosure is also applicable to other scannable sequential elements.

Moreover, the figures in this disclosure illustrate implementations using complementary metal-oxide semiconductor (CMOS) transistors, but the subject disclosure is also applicable to any other device capable of implementing digital logic including, but not limited to, bipolar transistors, tunnel transistors, gallium arsenide transistors, micro-electro-mechanical relays, Josephson junctions, and discrete components.

FIG. 1B is a diagram illustrating a digital circuit 120 with scannable sequential elements connected in a scan chain according to one or more implementations. The digital circuit 120 includes a plurality of blocks of combinational logic 130, 132 (sometimes referred to as a logic cloud) separated by banks of scannable flip-flops 140, 142, 144. In ordinary operation, the test enable (“TE”) signal 150 is 0 and the flip-flops copy the value from their respective data input (e.g., D) to their respective data output (e.g., Q) on the rising edge of clock φ 160. Hence, the circuit behaves as a pipeline. In test mode, the test enable signal is 1 and the flip-flops behave as a long shift register. Over a series of clock cycles, the contents of the flip-flops can be scanned out through a specific test output (e.g., TO output) and new contents can be shifted in through a specific test input (e.g., TI input).

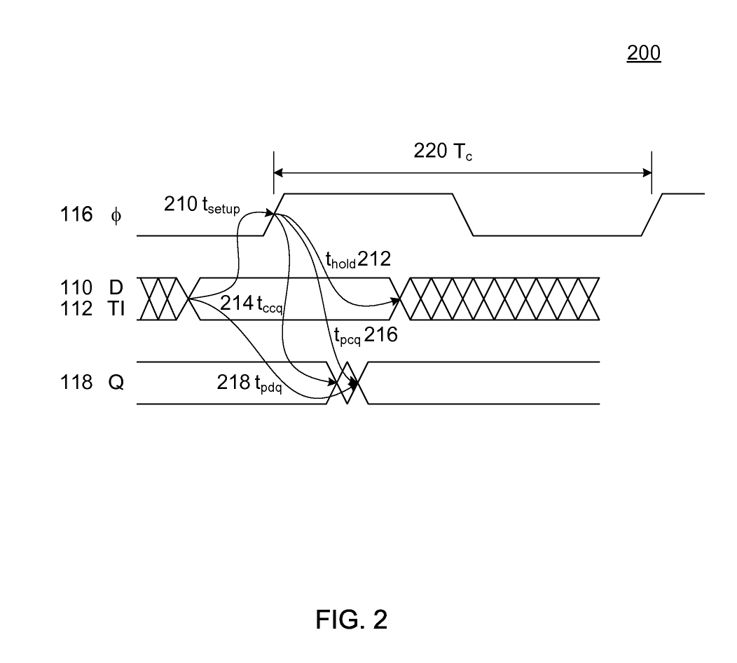

FIG. 2 is a diagram illustrating a timing diagram 200 of a sequential element according to one or more implementations. In this illustration, the timing diagram 200 shows that the data input 110 needs to stabilize by some setup time tₛₑₜᵤₚ 210 before the rising edge of the clock 116 and needs to remain stable for some hold time t_{hold} 212 after the rising edge of the clock so that the flip-flop can reliably sample the data. The data output 118 may begin changing after a clock-to-Q contamination delay t_{ccq} 214 in response to the rising edge of the clock and will certainly have stabilized by some clock-to-Q propagation delay t_{pcq} 216. The sequencing overhead t_{pdq} 218 is the time from when D must have stabilized until data output 118 becomes stable; this is tₛₑₜᵤₚ+t_{pcq}. The test input 112 also has setup and hold constraints relative to the rising edge of the clock 116.

The maximum speed of the digital circuit 120 is limited by the time for a signal to come out of a flip-flop (e.g. 140), propagate through a combinational logic block (e.g. 130), and setup at the next flip-flop (e.g. 142). If the logic block has a propagation delay t_{pd}, the clock period needs to be at least:

T_{c}=t_{pcq}+t_{pd}+tₛₑₜᵤₚ=t_{pdq}+t_{pd}

Therefore, it is important to minimize the sequencing overhead t_{pdq} 218 from the data input 110 to the data output 118.

During test mode, signals propagate directly from the output of one flip-flop to the input of the next, generally without combinational logic between flops. Hence, these test paths usually do not limit the speed of the system. However, the test input 112 needs to remain stable at the input of a flip-flop for some hold time 212 after the rising edge of the clock 116. If t_{ccq}>t_{hold}, the flip-flops alone is too fast to ensure this constraint. In such a case, the designer may need to insert delay elements, such as inverters, buffers, transmission gates, wires, and so forth, between the flip-flops in the scan chain. These delay elements increase the size, cost, and power of the circuit and are undesirable.

Moreover, some circuits have significant delays, called clock skew, between the clocks going to different flip-flops. When one flip-flop switches early and the next switches late because of clock skew, even more delay elements are required to satisfy the hold time. Therefore, it is important to minimize the hold time 212 on the test input 112 to reduce the number of delay elements in the system.

FIG. 3 is a diagram illustrating a transistor-level design of a scannable sequential element 300 according to one or more implementations. The flip-flop includes a master stage 302 and a slave stage 304. Clock inverter 370 produces a complementary clock φ_{b} 317. When the clock φ 116 is 0, the complementary clock φ_{b} 317 is 1. Similarly, when the clock φ116 is 1, the complementary clock φ_{b} 317 is 0. The pass gates 350, 352, 354, 356 are CMOS transmission gates that behave as switches. The pass gates have true and complementary control terminals; the complementary terminal is indicated with the circle. When the true control terminal is 0 and the complementary terminal is 1, the pass gate is OFF and the left side is isolated from the right side. When the true control terminal is 1 and the complementary terminal is 0, the pass gate is ON and the left side is electrically connected to the right side.

The master stage 302 includes three pass gates. Pass gates 350 and 352 serve as the scan multiplexer, while pass gate 354 serves as the master latch. When the test enable input 114 is 0, pass gate 350 is ON and pass gate 352 is OFF, so D flows through inverter 360 and pass gate 350 to node A 320. When the test enable input 114 is 1, pass gate 352 is ON and pass gate 350 is OFF, so TI flows through inverter 362 and pass gate 352 to node A 320. When φ 116 is 0, pass gate 354 is ON and node A 320 flows through to node Xb 324. Thus, the master stage 302 is transparent and samples the value from D or TI onto node Xb 324. When φ 116 is 1, pass gate 354 is OFF. Thus the master stage 302 is opaque and node Xb 324 retains the last sampled value. Inverter 364 inverts node Xb 324 to produce node X 322.

The slave stage 304 includes pass gate 356 that serves as the slave latch. When φ is 0, the pass gate is OFF and the slave is opaque, so Q retains its old value. When φ is 1, the pass gate is ON and the slave is transparent, so the value at node Xb 324 flows through the pass gate 356 and inverters 366 and 368 to the data output 118.

When the master stage 302 is opaque, a feedback tristate inverter 380 turns ON to retain the value at node X 322. When the master is transparent, feedback tristate inverter 380 turns OFF to avoid contention (i.e. to avoid fighting the value flowing through the master). Similarly, feedback tristate inverter 382 retains the value at node Qb 326 while the slave is opaque.

In summary, the master and slave stages behave as two locks on a canal. When φ is 0, the D or TI input is selected (based on TE) and flows through the transparent master to node X 322, where it is blocked by the opaque slave. When φ rises to become 1, the slave becomes transparent and the value at node X 322 flows through to Q while the master becomes opaque and isolates node X 322 from changes on the inputs. Hence, the flip-flop copies D to Q on the rising edge of φ and retains its value at all other times.

The master stage 302 has a data path and a test path. The data path is the path from D to node X 322 through inverters 360 and 364 and pass gates 350 and 354. The test path is the path from TI to node X 322 through inverters 362 and 364 and pass gates 352 and 354. Both paths involve two pass gates and two inverters, so they are relatively slow. This slow delay means the setup time is relatively large but the hold time is relatively short.

Referring to FIG. 3, each of the pass gates 350, 352, 354, 356 includes a full CMOS transmission gate with an nMOS transistor (sometimes referred to as a transistor of n-type material) as well as a pMOS transistor (sometimes referred to as a transistor of p-type material) working together to act as a switch. However, in other implementations, a pass gate could include a single nMOS transistor, a single pMOS transistor, a micro-electromechanical relay, or any other switch-like element that can pass or block a logic value. Some of these forms of pass gates have only a single control terminal. Moreover, in other implementations, an inverter or other logic gate may be merged with the pass gate to form a tristate. In one or more implementations, the tristate can be considered to include a pass gate.

Various inverters and/or tristate inverters in the scannable sequential element 300 may be replaced with more complex gates to integrate logic into the flip-flop. For example, the inverter at the data input 110 can be replaced with a 2-input NAND gate also coupled to RESETb to create a synchronously resettable flip-flop. Similarly the inverter can be replaced with an inverting multiplexer to create a mux-flop.

A pulsed latch can be used in place of a flip-flop. A scannable pulsed latch includes a master stage but not a slave stage of the scannable sequential element 300. A scannable pulsed latch may further include an additional clocked pass gate to prevent hold time problems when operated in test mode.

In one or more implementations, a test input, a test enable input and a test path may be sometimes referred to as a scan input, a scan enable input, a scan path, respectively.

As stated above with respect to FIG. 1B, scanning techniques include sequential elements integrated into a scan chain to observe and control the state of each sequential element. Logically, the scanning techniques involve adding a multiplexer to an input of each sequential element to choose the appropriate input source. However, the multiplexer increases a sequencing overhead since combinational gates may be present. Because there is no data delay on a test input, hold time requirements at the test input become a problem.

Moreover, scanning techniques include selectively gating a clock input of each sequential element to reduce the sequencing overhead. However, clock gating increases the number of clocked transistors in the scan chain, which increases power consumption. In addition, clock gating can delay the clock input, resulting in a longer hold time requirement at each sequential element. If the hold time is too long, the designer needs to insert delay elements into the scan chain, increasing the size, cost, and power consumption of the circuit

In applications such as building high-speed circuits, sequential elements with short setup time and clock-to-Q delay between the data input and data output may be desired. In one or more implementations, the delay between the test input and data output may be less significant, but the test input needs a short hold time. In one or more implementations, if the hold time is too long, delay elements may need to be inserted into the scan chain, increasing the size, cost, and power consumption of the circuit. Hence, there is a need for, among others, sequential elements having fast delay on the data input and short hold time on the test input according to one or more implementations.

As such, a scannable sequential element with skew tolerance and short scan hold times in accordance with one or more implementations is provided, which uses a single pass gate (sometimes referred to as a transmission gate) on a data path that only receives data signals, controlled by a gated clock signal, for low sequencing overhead. Additionally, the scannable sequential element uses series pass gates on a test path that only receives test signals, respectively controlled by the clock signal and a test enable signal, for a relatively short hold time requirement on the test path.

In one or more aspects, a clock signal is logically combined with the test enable signal to form the gated clocked signal. An overlap between the clock signal and gated clocked signal exists that creates a transparency period during which pass gates located on the data path are configured to toggle simultaneously. In turn, the clock overlap significantly reduces the sequencing overhead, which speeds up the data path between master and slave portions of the scannable sequential element. In addition, the clock overlap provides for an increase in tolerance to clock skewing, which in turn, provides for increased hold times. In one or more implementations, the clock overlap can be increased by adding buffers, series transistors or capacitive loads.

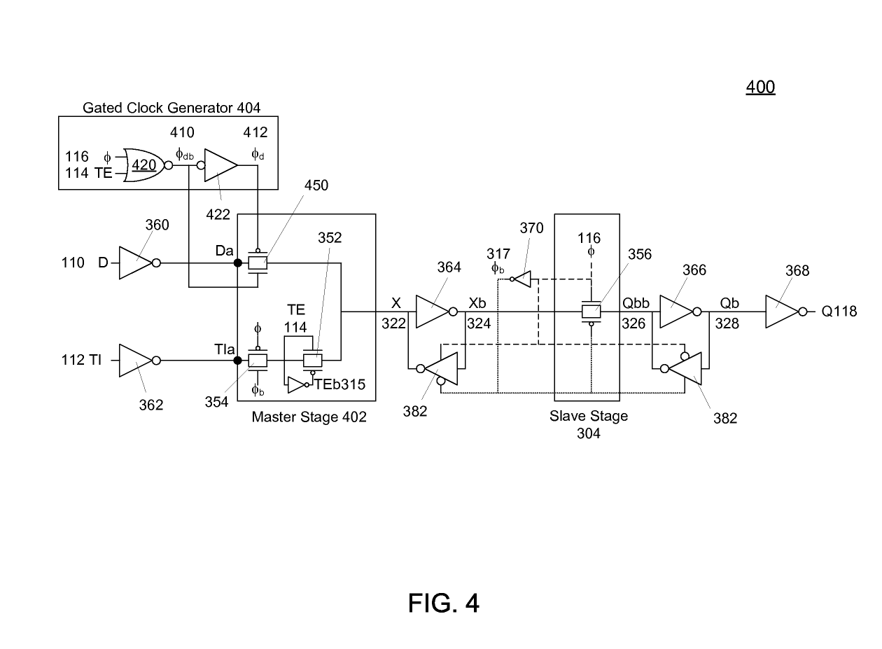

FIG. 4 is a diagram illustrating a scannable sequential element 400 according to one or more implementations. Here, the scannable sequential element 400 may include a master stage 402 and a slave stage 304. The master stage 402 has a data path and a test path. The data path may be a path from Dₐ to node X 322 through a pass gate 450. The test path may be a path from TIₐ to node X 322 through pass gates 352 and 354. The two pass gates 350 and 354 on the master stage data path of the scannable sequential element 300 are replaced by a single pass gate 450 controlled by a gated clock generator 404. In one or more aspects, the node X 322 is configured to receive one or more data signals when the data path is ON and the test path is OFF, and one or more test signals when the test path is ON and the data path is OFF.

In one or more aspects, a data path is configured to receive (or process or provide) one or more data signals but not any test signals (or test inputs). In one or more aspects, a test path is configured to receive (or process or provide) one or more test signals but not any data signals (or data inputs). In some implementations, the master stage 402 may include less than or greater than the number of components shown in FIG. 4.

When the test enable input 114 is 0, the gates 420 and 422 of gated clock generator 404 produce gated clocks φ_{db} 410 and φ_{d} 412, respectively, that are inverted and delayed versions of the clock φ 116. Thus, the data path is ON when φ 116 is 0 and OFF when φ 116 is 1. When TE is 1, gated clocks φ_{db} 410 and φ_{d} 412 are held at 0 and 1, respectively, so the data path is OFF. However, the test path behaves just as it did in master stage 302. Thus, the master stage 402 behavior is unchanged from 302, but one pass gate is removed from the data path, reducing the setup time on the data input. In summary, the scannable sequential element 400 is faster on the D input than the scannable sequential element 300, while maintaining a short hold time on the TI input. In one or more aspects, the gate 420 is a NOR gate and the gate 422 is an inverter. In one or more aspects, the gated clock generator 404 may produce the complementary clock φ_{b} 317, which is the complement of the clock φ 116.

Note that the two pass gates 352 and 354 from the master stage test path of the scannable sequential element 300 are preferably swapped in the master stage 402. The pass gate 354 toggles with φ 116, even when the test path is not active. By making this swap, the pass gate 354 is isolated from the node X 322, reducing the capacitance on the node X 322. Although the flip-flop generally will function with either ordering of pass gates 352 and 354, the arrangement in the scannable sequential element 400 may be faster and consume less power.

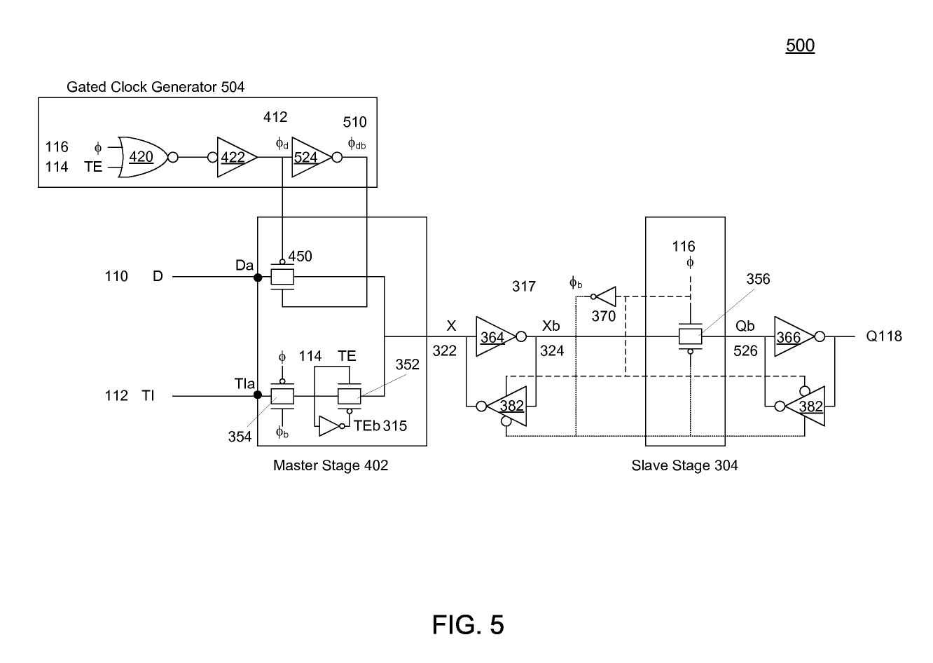

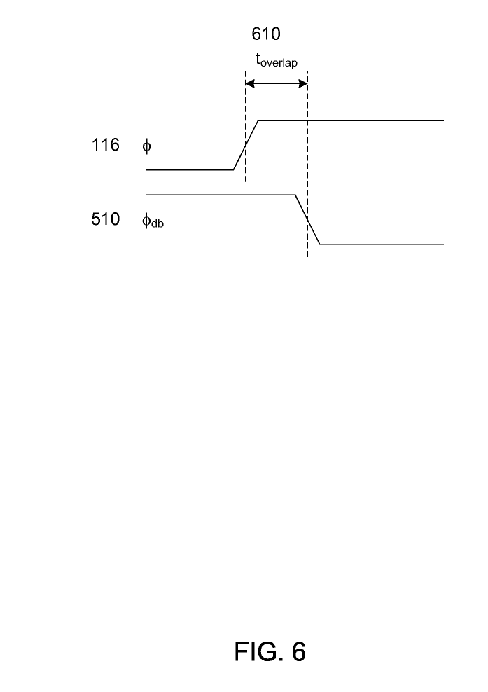

FIG. 5 is a diagram illustrating a scannable sequential element 500 according to one or more implementations. The inverters at the data input 110 and the test input 112 and output inverter 368 can be removed to save delay, area, cost, and power. Now the data path from D to node X 322 involves only one pass gate 450. This comes at the expense of heightened sensitivity to noise on the inputs and outputs. The gated clock generator 504 adds gate 524 so the complementary clock φ_{db} 510 is also delayed. In one or more aspects, the gate 524 is an inverter. This produces a beneficial transparency window that further reduces delay, as discussed in reference to FIG. 6. As with an ordinary flip-flop, various logic gates may be substituted into the scannable sequential elements 400 and 500 to perform synchronous or asynchronous set/reset or other logic functions. In some implementations, the master stage 402 may include less than or greater than the number of components shown in FIG. 5.

FIG. 6 is a diagram illustrating a transparency window according to one or more implementations. The transparency window is produced by overlapping clocks. The slave stage 304 in the scannable sequential element 500 is transparent when φ 116 is 1. The data path of the master stage 402 is transparent when φ_{db} 510 is 1. As the figure illustrates, the delay through gates 420, 422, and 524 of gated clock generator 504 causes φ 116 and φ_{db} 510 to be simultaneously 1, resulting in a transparency window of width tₒᵥₑᵣₗₐₚ 610 when both master and slave stage are transparent. During this transparency window, D 110 can pass through to Q without waiting for either the master or slave. Hence, the delay is shorter.

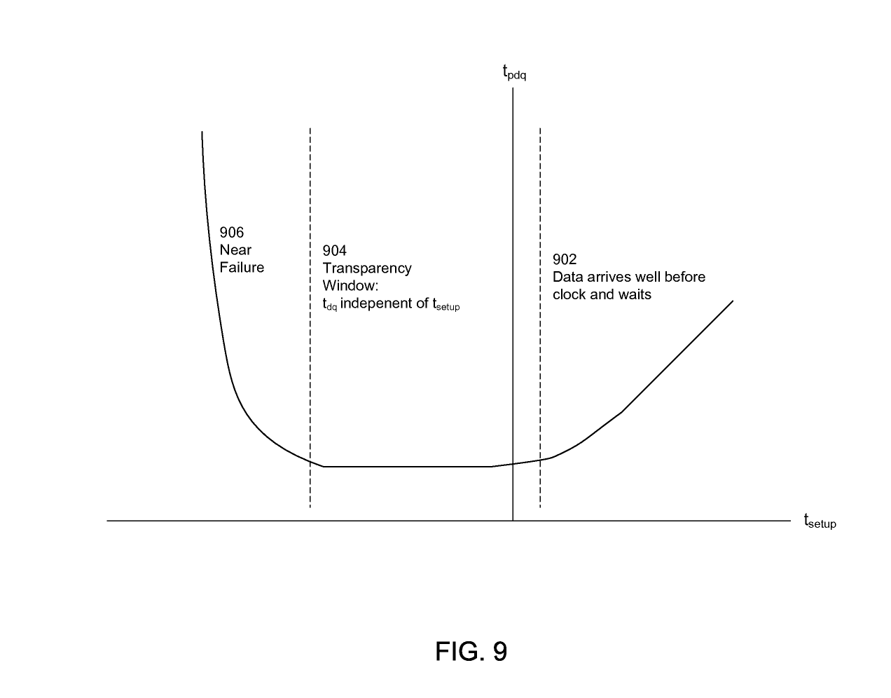

Moreover, the flip-flop demonstrates a degree of skew-tolerance because the sequencing overhead becomes independent of the clock or data arrival time during the transparency window, as will be shown in FIG. 9. Skew tolerance makes system performance even faster. However, the overlap also increases the hold time on the D input because D needs to not change until sometime after the falling edge of φ_{db}. The test path does not involve overlapping clocks, so the hold time remains short. tₒᵥₑᵣₗₐₚ depends on the delay of the gated clock generator and may range from half of a gate delay up to many (e.g. 10) gate delays.

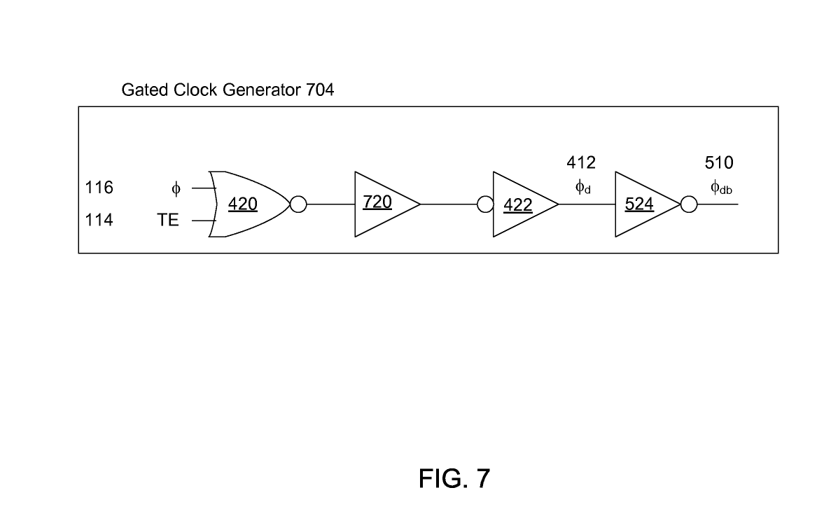

FIG. 7 is a diagram illustrating a gated clock generator 704 producing a wider transparency window according to one or more implementations. As compared to gated clock generator 504, gated clock generator 704 adds a delay element 720 to increase the delay on φ_{d} and φ_{db}. This results in φ_{db} switching later, increasing tₒᵥₑᵣₗₐₚ 610. The wider transparency window provides greater skew tolerance at the expense of longer hold time on the D input. By using buffers or other delay elements 720 with different delays, the designer can tune the width of the transparency window for various circuit requirements.

During the transparency window, the scannable sequential elements 400 and 500 have both the data path pass gate 450 and the feedback tristate inverter 380 simultaneously ON. The contention between the pass gate and the tristate increases the data path delay in the master stage 402. Therefore, it can be minimized.

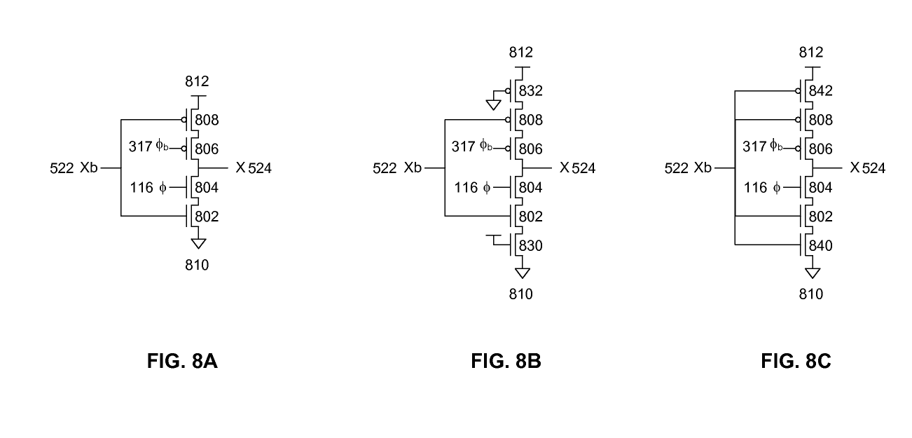

FIGS. 8A-8C illustrate three transistor-level designs for feedback tristate inverter 380 to minimize contention. In FIG. 8A, a tristate inverter uses minimum width transistors 802, 804, 806, 808 so that the output drive is weak. In this respect, the minimum width may be referred to as a defined feature size of the transistors. In one or more aspects, the transistors may be configured with channel lengths that are greater than the defined feature size. That is, the channel lengths can be greater than minimum to further weaken the tristate. In some advanced processes, it is not possible to increase channel length. FIG. 8B shows an another implementation of a weak tristate inverter that adds series transistors 830 and 832 tied to VDD 812 and GND 810 so that they are always ON. These extra transistors further weaken the inverter. However, adding the wires for VDD and GND to the tristate layout may be inconvenient. FIG. 8C shows another implementation of a weak tristate that uses series transistors 340 and 342 tied to the input Xb 522. This provides the same benefit of reducing contention and simplifies wire but increases the capacitive load on Xb 522 and hence slightly slows the scannable sequential element 500.

In one or more aspects, feedback tristates can also be constructed from a gate (including but not limited to an inverter, NAND, or NOR) followed by one or more pass gates.

FIG. 9 is a diagram illustrating a sequencing overhead of a scannable sequential element according to one or more implementations. The horizontal axis indicates the time that the data 110 sets up before the rising edge of the clock 116. The vertical axis indicates the sequencing overhead t_{pdq} 218. If the setup time 210 is large (zone 902), the clock-to-Q propagation delay t_{pcq} 216 reaches a constant minimal value and the sequencing overhead increases linearly with setup time. During the transparency window when both master and slave stages are transparent (zone 904), the data flows directly through from D to Q with a delay that is independent of the setup time. If the data arrives too late (zone 906), delay increases dramatically as the flip-flop approaches the point of failure.

One or more implementations are performed by one or more integrated circuits, such as application specific integrated circuits (ASICs) or field programmable gate arrays (FPGAs). In one or more implementations, such integrated circuits execute instructions that are stored on the circuit itself. In one or more aspects, the term “integrated circuit” includes, but is not limited to, a design tool output file as binary code encompassing the overall physical design of the integrated circuit, a data file encoded with code representing the overall physical design of the integrated circuit, a packaged integrated circuit, or an unpackaged die. The data file can include elements of the integrated circuit, interconnections of those elements, and timing characteristics of those elements (including parasitics of the elements).

The terms “input” and “output” as used herein may refer to a non-transitory signal or a physical item such as a node, a circuit, a block, a pad, a terminal, a port, a raised semiconductor structure, and other similar physical items.

The various illustrative blocks, elements, components, and methods described herein may be implemented as electronic hardware. Various illustrative blocks, elements, components, and methods have been described above generally in terms of their functionality. Whether such functionality is implemented as hardware depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

The predicate words “configured to” and “operable to” do not imply any particular tangible or intangible modification of a subject, but, rather, are intended to be used interchangeably. In one or more implementations, a receiver configured to receive and process an operation or a component may also mean the receiver being operable to receive and process the operation.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. Such disclosure may provide one or more examples. A phrase such as an aspect may refer to one or more aspects and vice versa, and this applies similarly to other phrases.

Any implementation described herein as an “example” is not necessarily to be construed as preferred or advantageous over other implementations. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A scannable sequential element, comprising:
a master stage comprising:
a data path configured to receive a data input;
a pass gate located on the data path and configured to selectively pass the data input;
a test path coupled to the data path and configured to receive a test input; and
a plurality of pass gates located on the test path and configured to selectively pass the test input,
wherein the data path has only one pass gate.

2. The scannable sequential element of claim 1, comprising:
a data output; and
a slave stage coupled between the master stage and the data output and configured to receive the data input or the test input from the master stage.

3. The scannable sequential element of claim 2, comprising:
a clock generator coupled to the master stage and the slave stage and configured to receive a clock input and a test enable input.

4. The scannable sequential element of claim 3, wherein the clock generator is configured to generate a plurality of clock signals based on the clock input and the test enable input.

5. The scannable sequential element of claim 4, wherein the plurality of clock signals comprises a gated clock signal and a complementary gated clock signal, wherein the complementary gated clock signal is a complement of the gated clock signal.

6. The scannable sequential element of claim 4, wherein the plurality of clock signals comprises a complementary clock signal that is a complement of the clock input.

7. The scannable sequential element of claim 2, wherein the slave stage comprises one or more pass gates coupled to the data output, the one or more pass gates coupled to a clock input and a complementary clock signal that is a complement of the clock input.

8. The scannable sequential element of claim 7, comprising one or more logic gates coupled to the data output and the one or more pass gates, the one or more logic gates configured to receive the clock input and the complementary clock signal and configured to feed back an output signal from the slave stage based on the clock input and the complementary clock signal.

9. The scannable sequential element of claim 1, wherein one of the plurality of pass gates located on the test path is coupled to a clock input and a complementary clock signal that is a complement of the clock input.

10. The scannable sequential element of claim 1, wherein the pass gate located on the data path is coupled to a gated clock signal and a complementary gated clock signal that is a complement of the gated clock signal.

11. The scannable sequential element of claim 1, wherein one of the plurality of pass gates located on the test path is configured to receive a test enable input and a complementary test enable signal that is a complement of the test enable input.

12. A scannable sequential element with skew-tolerance, comprising:
a master stage comprising:
a data input configured to receive a data input signal;
a test input configured to receive a test input signal;
a test enable input configured to receive a test enable signal;
a clock input configured to receive a clock input signal;
a first internal node;
a second internal node;
a first pass gate coupled between the data input and the first internal node and configured to selectively pass the data input signal toward the first internal node based on the clock input signal;
a second pass gate coupled between the test input and the first internal node and configured to selectively pass the test input signal toward the first internal node based on the test enable signal;
a third pass gate coupled between the test input and the first internal node and configured to selectively pass the test input signal toward the first internal node, wherein the second pass gate and the third pass gate are coupled in series; and
a first logic gate coupled between the first internal node and the second internal node; and
a slave stage coupled to the master stage and comprising:
a data output;
a third internal node;
a fourth pass gate coupled between the second internal node and third internal node and configured to selectively pass the data input signal or the test input signal based on the clock input signal; and
a second logic gate coupled between the third internal node and the data output.

13. The scannable sequential element claim 12, comprising:
a gated clock generator coupled to the clock input and the test enable input and configured to generate a gated clock signal,
wherein the first pass gate is configured to receive the gated clock signal.

14. The scannable sequential element claim 12, comprising:
a clock generator coupled to the clock input and configured to generate a complementary clock signal that is a complement of the clock input,
wherein the second pass gate and the fourth pass gate are configured to receive the clock input signal and the complementary clock signal, and
wherein the test enable input is coupled to the third pass gate.

15. The scannable sequential element claim 13, wherein the first pass gate and the fourth pass gate are configured to be simultaneously transparent during a transparency window if the clock input signal is configured to rise before the gated clock signal is configured to fall.

16. The scannable sequential element claim 15, wherein the gated clock generator comprises a delay element to increase the transparency window.

17. The scannable sequential element claim 12, comprising:
a feedback tristate coupled to the first internal node and the second internal node and configured to feed back an internal signal from the second internal node to the first internal node.

18. The scannable sequential element claim 17, wherein the feedback tristate comprises one or more transistors with channel lengths that are greater than a defined feature size.

19. The scannable sequential element claim 17, wherein the feedback tristate comprises a plurality of transistors of a first type and a plurality of transistors of a second type coupled in series, wherein the first type is n-type material and the second type is p-type material.

20. The scannable sequential element claim 12, wherein the first logic gate and the second logic gate comprise inverters.
